(19) United States
(12) Patent Application Publication
(10) Pub. No.: US 2002/0155674 A1
(43) Pub. Date: Oct. 24, 2002

(54) Method for preventing boron penentration of a MOS transistor

(76) Inventors: Chi-King Pu, Chia-I City (TW); Yi-Fan Chen, Tai-Chung City (TW)

Correspondence Address: NAIPO (NORTH AMERICA INTERNATIONAL PATENT OFFICE), P.O. BOX 506, MERRIFIELD, VA, 22116, US

(21) Appl. No.: 09/836,259

(22) Filed: Apr. 18, 2001

(51) Int. Cl. H01L 21/331

(52) U.S. Cl. 438/369

(57) ABSTRACT

A tetra-ethyl-ortho-silicate (TEOS) layer is first deposited on the surface of a MOS transistor followed by the deposition of a borophosposilicate glass (BPSG) layer atop the TEOS layer. Thereafter, an ion implantation process of BF₂⁺ is performed to alter the dopant concentration in the gate conduction layer of the PMOS transistor. Both the TEOS layer and the BPSG layer suppress both free fluorine and boron ions from entering the gate during the ion implantation process of BF₂⁺ to prevent boron penetration of the MOS transistor and stabilize the threshold voltage of the MOS transistor.

### BACKGROUND OF THE INVENTION

1. Field of the Invention

The present invention relates to a method of preventing boron penetration of a PMOS transistor.

2. Description of the Prior Art

Continuing increase in the integration of semiconductor devices has led to the use of a type of CMOS transistor device, composed of two complementary PMOS and NMOS transistors. The CMOS transistor device is widely used in the field of ultra large semiconductor integration (ULSI) due to its advantage of low energy consumption. In order to increase the speed of the CMOS devices, the microelectronics industry has for the past two decades aggressively scaled down channel length dimensions. However, a reduction in channel length requires the thickness of the gate oxide to be likewise reduced so as to avoid high threshold voltage or short channel effects.

Please refer to FIG. 1 to FIG. 9. FIG. 1 to FIG. 9 are cross-sectional diagrams of a prior method for manufacturing a CMOS transistor. As shown in FIG. 1, a semiconductor wafer 10 containing a P-type silicon substrate 12 is first provided, and a pad oxide layer 14 composed of silicon oxide and a silicon nitride layer 16 are formed on the surface of the semiconductor wafer 10 respectively. A photo-etching-process (PEP) is then performed to define active areas in the pad oxide layer 14 and silicon nitride layer 16, as shown in FIG. 2.

Thereafter, as shown in FIG. 3, a photoresist layer 18 is formed on the surface of the semiconductor wafer 10 followed by performing a lithography process to define the position of an N-well in the photoresist layer 18. An ion implantation process 19 is performed to implant N-type dopants in the silicon substrate 12 to form the N-well. Finally, a thermal drive-in process functions to form the N-well 20 in the silicon substrate 12 and the photoresist layer 18 is removed, as shown in FIG. 4.

As shown in FIG. 5, the remaining pad oxide layer 14 and silicon nitride layer 16 on the surface of the semiconductor wafer 10 are completely removed, and ion implantation processes are performed to implant the threshold voltage of the n-well 20 and the P-type silicon substrate 12 respectively. A gate oxide layer 22, a polysilicon layer 24 and a tungsten silicide layer 26 are formed on the surface of the semiconductor wafer 10 respectively. An photo-etching-process is then performed to define and form gate patterns in the gate oxide layer 22, polysilicon layer 24 and tungsten silicide 26 for forming a PMOS transistor gate 27 on the N-well 20 and a NMOS transistor gate 28 on the P-type substrate 12 respectively, as shown in FIG. 6.

As shown in FIG. 7, two ion implantation processes are performed in sequence to form lightly doped drains (LDD) 30 on the two sides of the silicon substrate 12 of PMOS and NMOS respectively. A photoresist layer (not shown) is formed first as a mask on the P-type substrate 12 followed by performing an ion implantation process, using boron ions as dopants, on the n-well 20 region. Following this, a photoresist layer (not shown) is formed as a mask on the n-well 20 and an ion implantation process is performed, using arsenic (As) or phosphorous (P) ions as dopants, on the P-type substrate 12.

As shown in FIG. 8, after forming the LDD 30 of each MOS transistor, a spacer 32 is formed around each gate 27, 28. Then two ion implantation processes are performed in sequence to form source 34 and drain 36 PMOS and NMOS respectively. A photoresist layer (not shown) is formed as a mask on the P-type substrate 12 followed by performing an ion implantation process on the n-well region 20, using boron (B) or fluoride boron (BF₂⁺) ions as dopants. A photoresist layer (not shown) is then formed as a mask on the n-well region 20 followed by an ion implantation process, using arsenic (As) or phosphorous (P) ions as dopants, on the P-type substrate 12. Finally, a rapid thermal anneal process is performed to activate dopants in each doped area to complete the prior art process of forming a CMOS transistor.

FIG. 9 is a schematic diagram of a CMOS transistor according to the prior art. The CMOS transistor is formed on the P-type silicon substrate 12 of a semiconductor wafer 10 and an N-well 20 is formed in the P-type substrate 12. A gate 27 of a PMOS transistor is formed on the N-well 20 and a gate 28 of a NMOS transistor is formed on the P-type substrate 12. A LDD 30, source 34 and drain 36 are formed on two sides of substrate 12 of each MOS transistor. A plurality of shallow trench isolation (STI) structures 38 are formed in the substrate 12 for separating and protecting each PMOS and NMOS transistor.

However, a disadvantage occurs in the use of BF₂⁺ as a dopant in the ion implantation process on the PMOS transistor. For instance, the ion source contains both a small amount of free fluorine (F) and boron (B) ions, whereby the presence of fluorine ions enhances the diffusion of boron ions. Since the thickness of the gate oxide layer is decreased due to the scaling-down process of channel length dimensions to increase the speed of the MOS device, boron ions readily penetrate through the gate oxide layer 30 to enter the underlying silicon substrate 10. As a result, both positive shifts in the threshold voltage as well as an increase in electron trapping occur, and the reliability of the PMOS transistor device decreases.

### SUMMARY OF THE INVENTION

It is the primary object of the present invention to provide a method of preventing boron penetration of a PMOS transistor.

The method of the present invention first involves the deposition of a tetra-ethyl-ortho-silicate (TEOS) layer on the surface of the MOS transistor, followed by the deposition of a borophosposilicate glass (BPSG) layer atop the TEOS layer. An ion implantation process, using BF₂⁺ as the dopant, is then performed to alter the dopant concentration in the gate conduction layer of the PMOS transistor. Both the TEOS layer and the BPSG layer suppress free fluorine and boron ions from entering both the gate conduction layer and the silicon substrate during the ion implantation process. As a result, boron penetration of the MOS transistor is prevented and stabilization of the threshold voltage of the MOS transistor is achieved to improve the overall property of the device.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 8 are cross-sectional diagrams of a method of manufacturing a CMOS transistor according to the prior art.

FIG. 9 is a schematic diagram of a CMOS transistor according to the prior art.

FIG. 10 to FIG. 11 are cross-sectional diagrams of a method for performing an ion implantation process on a PMOS transistor according to the present invention.

### DETAILED DESCRIPTION OF THE PREFERRED EMBODIMENT

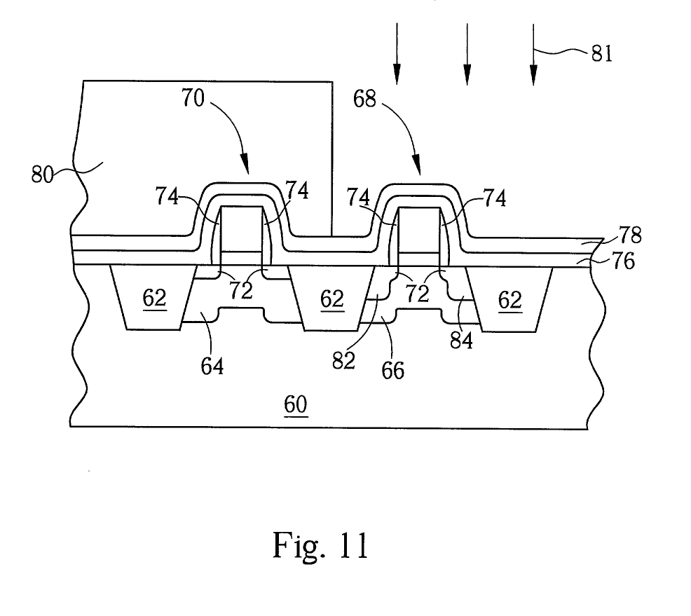

Please refer to FIG. 10 to FIG. 11. FIG. 10 to FIG. 11 are cross-sectional diagrams of a method for performing an ion implantation process on a PMOS transistor according to the present invention. As shown in FIG. 10, a plurality of isolation regions 62, such as shallow trench isolation (STI) structures or field oxide (FOX) regions are positioned on the silicon substrate 60 of the semiconductor wafer for separating the P-well 64 and the N-well 66. The gates 68,70 of NMOS and PMOS transistors are formed on the P-well region 64 and the N-well region 66, respectively. Both the gates 68,70 are composed of an undoped polysilicon layer, with a spacer 74 and a LDD 72 positioned around each gate 68,70.

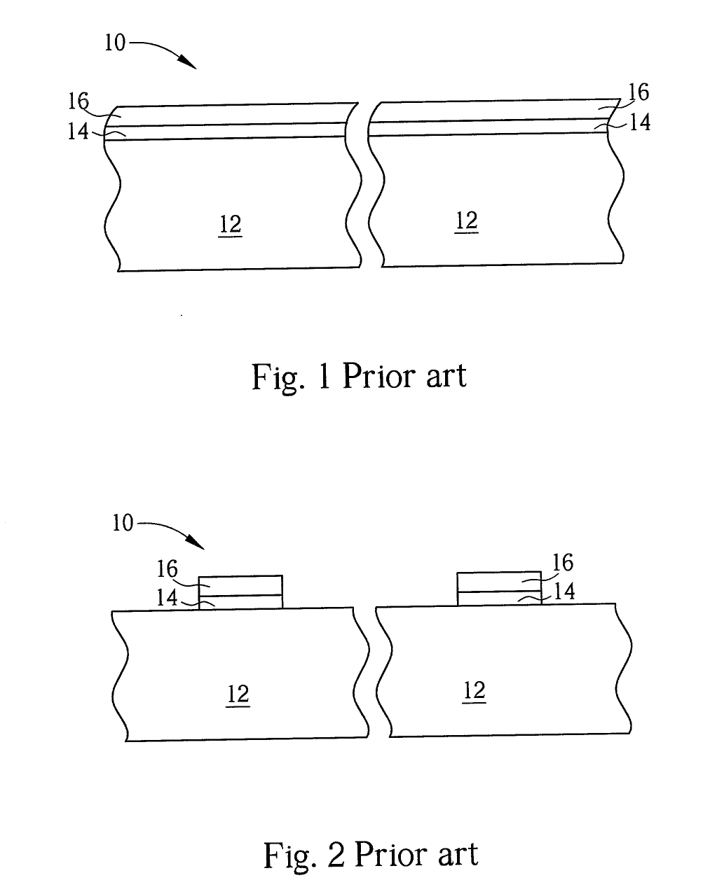

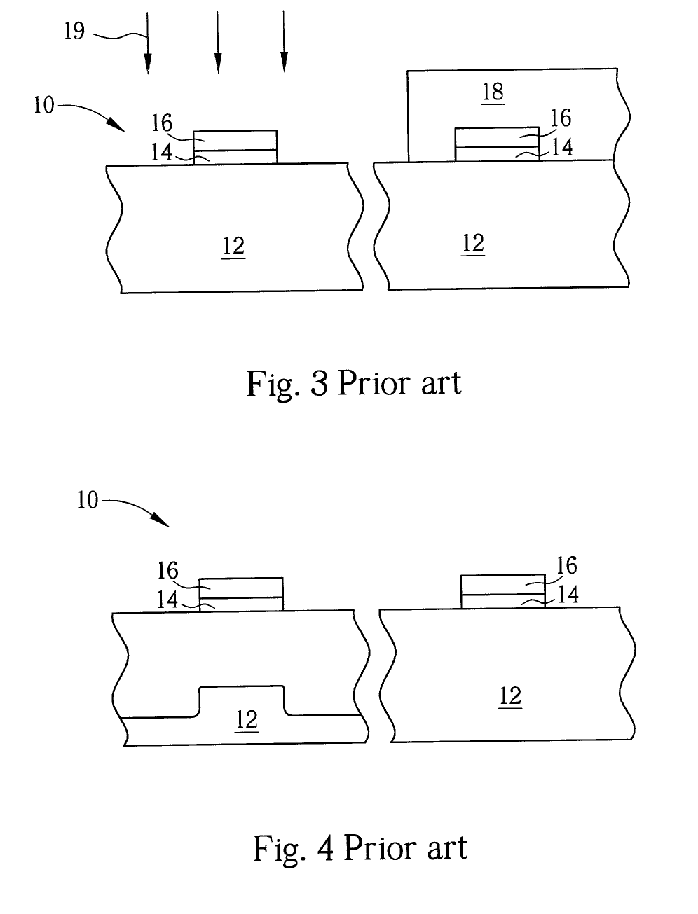

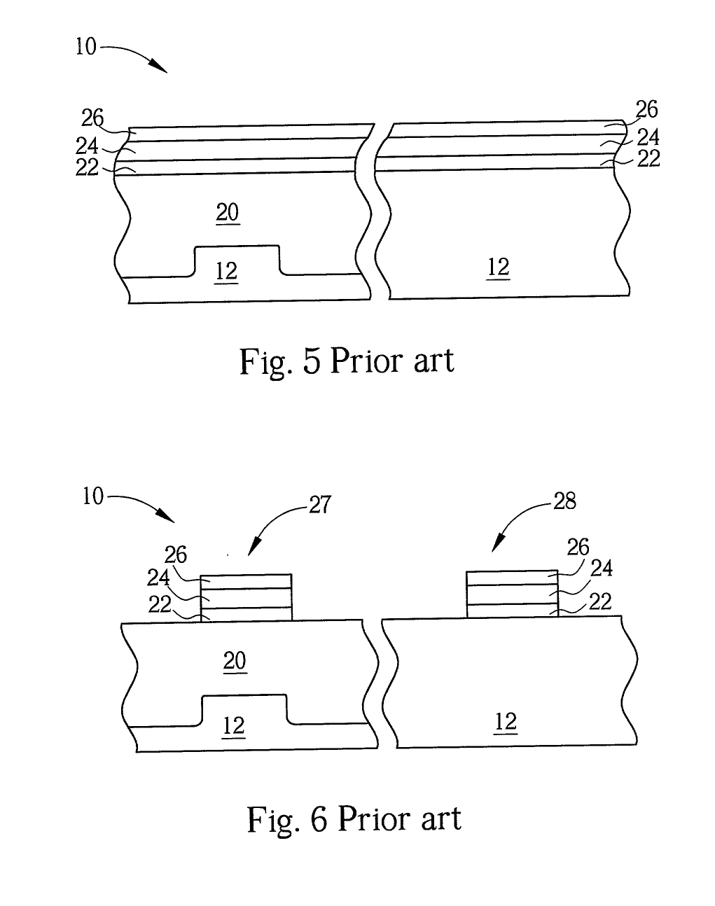

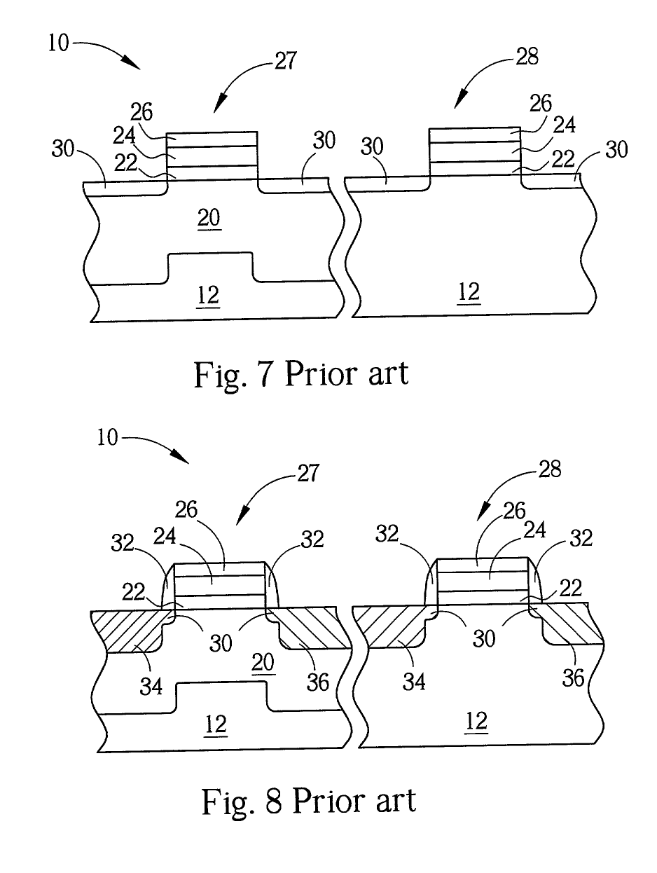

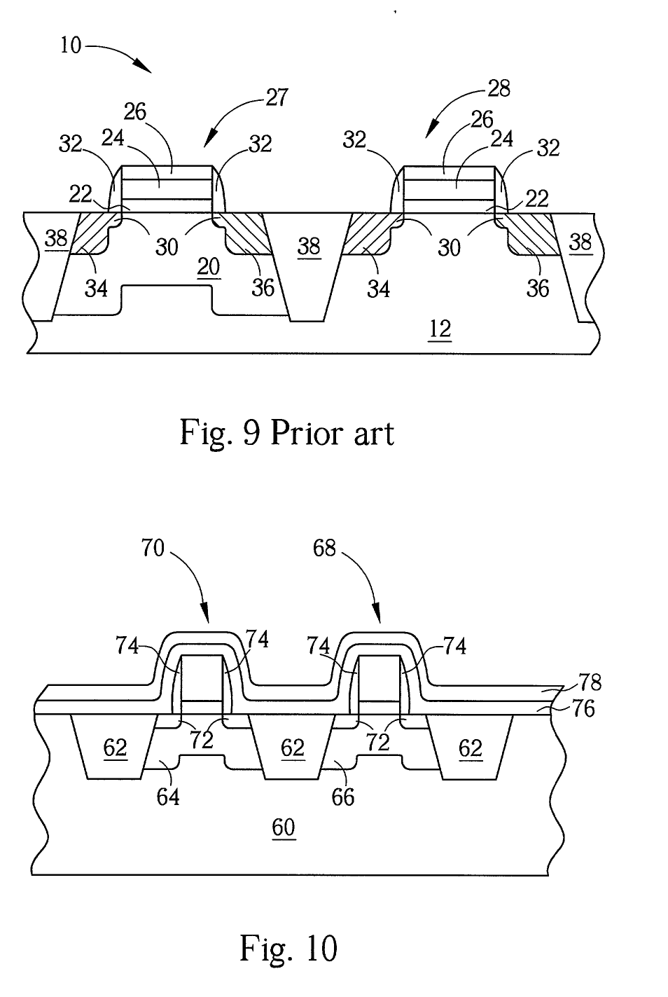

The process steps of the present invention method are similar to that of the prior art method shown in FIG. 1 to FIG. 9. The primary difference between the method of the present invention and that of the prior art (as shown in FIG. 1 to FIG. 9) is that in the present invention, both a tetra-ethyl-ortho-silicate (TEOS) layer 76 and a borophosposilicate glass (BPSG) layer 78 are formed on the surface of the silicon substrate 60, respectively, following the formation of the gates 68,70, spacer 74 and LDD 72, to suppress both free fluorine (F−) and boron ions (B+) from entering the gate 68 of the PMOS transistor.

As shown in FIG. 11, a photoresist layer 80 is formed as a mask on the P-well 64. An ion implantation process 81, using BF₂⁺ as a dopant, is performed to alter the dopant concentration in the gate 68 conduction layer of the PMOS transistor, and simultaneously, to form the source 82 and drain 84 of the PMOS transistor. Thereafter, the photoresist layer 80 is removed and another photoresist layer is formed as a mask on the N-well 66. Arsenic (As) ions or phosphorous (P) ions are used as dopants to adjust the dopant concentration in the gate 70 conduction layer of the NMOS transistor, and simultaneously, to form the source (not shown) and the drain (not shown) of the PMOS transistor.

The sequence of implanting the PMOS transistor and the NMOS transistor is only a design choice of which the diffusive property of the dopant is a factor. Another dielectric material may also be directly deposited on the TEOS layer 76 and the BPSG layer 78 following the ion implantation process of BF₂⁺, to form a composite insulation layer to isolate and protect the NMOS and PMOS transistors.

Since the BPSG layer 78 is formed by a chemical vapor deposition (CVD) method and the boron concentration of the BPSG layer 78 is not at its saturated concentration, free boron ions during the ion implantation process of BF₂⁺ penetrate and become trapped within the BPSG layer 78. The oxygen atoms of the TEOS layer 76 replace the fluorine ions so as to trap the free fluorine ions in the TEOS layer 76 during the ion implantation process of BF₂⁺.

In other words, the method of the present invention to prevent boron penetration of PMOS transistors involves first forming a TEOS layer and a BPSG layer, respectively, on the surface of the PMOS transistor. Then, an ion implantation process is performed to adjust the dopant concentration in the gate conduction layer of the PMOS transistor, and simultaneously, to form the source and the drain of the PMOS transistor.

In contrast to the prior art method of fabricating a CMOS transistor, the present invention process first involves forming a TEOS layer and a BPSG layer, respectively, on the surface of the PMOS transistor to suppress both free fluorine and boron ions from entering the gate of the PMOS transistor, followed by an ion implantation process of BF₂⁺ on the PMOS transistor. Therefore, boron penetration of PMOS transistors are effectively suppressed, and furthermore, the threshold voltage of PMOS transistors is stabilized to enhance the efficiency of the semiconductor products.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for reducing the electrical resistance of a gate of a metal oxide semiconductor (MOS) transistor, the gate being positioned on the substrate of a semiconductor wafer, the method comprising:
forming a protection layer on the top surface of the gate; and
performing an ion implantation process to implant a specific group of ions into the gate to alter the dopant concentration in the gate and reduce the electrical resistance of the gate;
wherein the protection layer is used to prevent free ions of non-specific groups from entering the gate during the ion implantation process.

2. The method of claim 1 wherein the protection layer is a composite structure of borophosposilicate glass (BPSG) and a tetra-ethyl-ortho-silicate (TEOS).

3. The method of claim 2 wherein the specific groups of ions contain boron fluoride ions or boron trifluoride ions, and the free ions contain boron ions and fluorine ions.

4. The method of claim 3 wherein the TEOS layer is used to trap the free fluorine ions.

5. The method of claim 3 wherein the BPSG layer is formed by chemical vapor deposition (CVD), and the boron content in the BPSG layer is not at the saturated concentration, and then free boron ions are trapped within the BPSG layer.

6. The method of claim 1 wherein the MOS transistor further contains a lightly doped drain (LDD), a source and a drain, the source and the drain being formed on the substrate around the gate by the ion implantation process.

7. A method for preventing boron penetration of a PMOS transistor, the method comprising:
depositing a TEOS layer on the surface of the MOS transistor;
depositing a BPSG layer on the TEOS layer; and
performing an ion implantation process of BF₂⁺ to alter the dopant concentration in the gate conducting layer of the PMOS transistor;
wherein both the TEOS layer and the BPSG layer suppress both free fluorine and boron ions from entering the gate during the ion implantation process of BF₂⁺ to prevent boron penetration of the MOS transistor and stabilize the threshold voltage of the MOS transistor.

8. The method of claim 7 wherein the BPSG layer is formed by chemical vapor deposition (CVD), and the boron content in the BPSG layer is not at the saturated concentration, and then free boron ions are trapped within the BPSG layer.

9. The method of claim 7 wherein the MOS transistor further contains a source and a drain, and the source and the drain are simultaneously formed by the ion implantation process of BF₂⁺.
